(19) United States
(12) Patent Application Publication
(10) Pub. No.: US 2009/0262577 A1
(43) Pub. Date: Oct. 22, 2009

(54) MULTI-LEVEL CELL FLASH MEMORY

(75) Inventor: Yasuyuki TANAKA, Kyoto-shi (JP)

Correspondence Address: DITTHAVONG MORI & STEINER, P.C., 918 Prince St., Alexandria, VA, 22314, US

(73) Assignee: Kyoto Software Research, Inc., Kyoto-shi (JP)

(21) Appl. No.: 12/495,078

(22) Filed: Jun. 30, 2009

(30) Foreign Application Priority Data
Dec. 26, 2006 (JP) 2006-349753

(51) Int. Cl. G11C 16/04

(52) U.S. Cl. 365/185.03

(57) ABSTRACT

Most drivers of flash memories used for embedded systems are often designed to use power from batteries, but not from a commercial power supply, and therefore are required to be protected against power failures. In addition, if a power failure occurs in the middle of programming a cell, the driver of an MLC flash memory may corrupt not only data in a page subjected to the program operation but also data already stored in the other pages in the same cell, which is an unrecoverable problem. According to the present invention, in order to write data into a block, the driver of the MLC flash memory has steps for preparing another block and writing identical data into corresponding pages of the two blocks alternately and makes it possible to write the data without data loss even if a power discontinuity or power failure occurs.

### BACKGROUND OF THE INVENTION

1. Field of the Invention

The present invention relates to an MLC flash memory with guaranteed protection against power failures and to a technique of writing data into cells of the MLC flash memory.

2. Description of the Related Art

Multi-level cell (MLC) flash memories comprise cells, each of which can represent 4, 8 or 16 levels (expressed by multi-bit values) which are numbers raised to the power of two. To store a multi-bit value in a cell, the MLC flash memories are conceptually designed to include a plurality of storage layers stacked on top of each other for convenience of understanding, and, in other words, all the cells are composed of the plurality of storage layers. Each of the layers in a cell can store one bit of information. A plurality of cells are collectively termed a page, a group of pages is termed a block, and a group of blocks makes up a memory. A 4-level (2-bit/cell) flash memory cell includes two storage layers, an 8-level (3 bit/cell) cell includes three storage layers, and a 16-level (4-bit/cell) cell includes four storage layers. When no data is programmed, each storage layer of every cell represents the state of “1”, but stores a “0” with changes in the state.

A description will be made about the configuration of a 4-level (2-bit/cell) flash memory having two storage layers per cell, the two layers each making up one page as shown in FIG. 1. FIG. 1 also indicates a single unit of a cell by a thick line. One of the layers (lower layer) is referred to as “page A”, while the other layer (upper layer) as “page B”. Each of the double-stacked pages A and B has 8 bits (1 byte) in a row and (2048+64) bytes in a column. The two pages A and B are paired with each other and 64 pairs (page A+page B) are contained in a block. As shown in FIG. 2, a single block, e.g., block 0, contains 64 pages of page A and 64 pages of page B, i.e. 128 pages in total (starting from page 0 and ending with page 127), but the pages A and the pages B corresponding to the pages A do not always appear in an alternating sequence. A page A is always placed on the top page (page 0) of a block, but the page to be placed next to the page A (in ascending page order) may be the page B corresponding to the page A or the other page A of a following pair (next page A+page B). In short, it cannot be determined whether a page B corresponding to a page A comes after the page A because it depends on the packaging method, the implementing way of the memory which depends on the design of the hardware. However, in a pair of pages (page A+page B), page A is defined as a lower number page than page B, and therefore always comes first. There are 2048 blocks in total, each of which includes pages placed in the same order (i.e., the positional relationship of pages A and pages B in the blocks is identical). Next, a description will be made about the programming of the MLC flash memory. Although programming is basically performed on a page-by-page basis, this description will be made on the assumption that a program operation is executed to page A and page B in a single cell. As shown in FIG. 3, when a cell is not programmed, page A and page B stores “1, 1” (referred to as “first state”), respectively, and after a “0” is programmed into only page A, the page A and page B change to “0, 1” (referred to as “second state”), respectively. Furthermore, when the page A stays in “0” and the page B is programmed to store a “0”, the page A and page B experience the state of “1, 0” (referred to as “third state”) and then change to the state of “0, 0” (referred to as “fourth state”). The states are shifted in increasing order of the states (i.e., from the first state to the fourth state), however, the states cannot be shifted in the decreasing order of the states (e.g., from the fourth state to the first state). If the data in a block is unprogrammed, the states stored in all the pages in the block return to the first state.

A phenomenon unique to MLC memories will be described. While both page A and page B are not programmed at all (first state), if only page A is programmed to store a “0”, the pages A and B shift to the next state (second state), i.e., page A is changed, but page B remains the same. In addition, programming a given cell always starts with page A before page B, and therefore programming page A to store a “0” does not affect page B. However, while page A has been programmed to store a “0” (second state), if page B is also programmed to store a “0” (fourth state), page B changes itself from “1” to “0”, but a phenomenon occurs in which page A changes itself from “0” to “1” and returns to “0” again (from the second state, via the third state, to the fourth state). Furthermore, while both page A and page B store a “1” (first state), if the page B is programmed to store a “0” (shifting to the third state), page B changes itself from “1” to “0”, but a phenomenon occurs in which page A changes itself from “1” to “0” and returns to “1” again (from the first state, via the second state, to the third state).

As described above, in MLC flash memories, programming page A with data does not provide any changes to page B, while programming page B with data causes the page A to change its state and then to return to the state. For measures to protect flash memories from power failures, a flash file drive which guarantees to protect only 2-level cell (1-bit/cell) flash memories (commonly known as “single level cell (SLC)” flash memory) from power failures is disclosed in the article entitled “The basics of a flash memory and development of a file system protection against power failures” in InterFace, issued in December, 2004, by Tsuneya Nagasawa.

The problems in the MLC flash memories are data corruption caused by sudden power failures. If a power failure occurs in the middle of programming page A, the state of the page A cannot be guaranteed. In addition, a power failure in the middle of programming page B may cause data corruption of not only page B but also page A because the program operation for page B transiently changes the value of page A. Worst of all, the value of page A that is not stored in any buffers can never be recovered. So far, there is no flash file driver that protects data in the MLC memories from power failures.

### SUMMARY OF THE INVENTION

The present invention is made to solve the aforementioned problems and has an object to provide guaranteed protection against power failures to a MLC flash memory.

The MLC flash memory according to the present invention represents more than two levels per cell. Every single cell has a plurality of storage layers for holding the multiple levels. A plurality of cells make up a block. The flash memory includes a plurality of blocks. The MLC flash memory has a program unit to write data into the cells. The program means selects two different blocks from the plurality of blocks and writes identical data into corresponding storage layers in the two selected blocks.

The program technique in which data is written in the plurality of distinct parts of a page provided in a cell of the MLC flash memory according to the present invention is designed to select two blocks from the plurality of blocks and to write identical data into the corresponding pages in the two selected blocks, which guarantees to protect the MLC flash memory from power failures.

There are some 2-level flash memories having guaranteed protection against power failures at present; however, such protection does not exist for MLC flash memories. Accordingly, the present invention creates a quite new value. In addition, the present invention is applicable not only to portable devices but also vehicle-installed devices that often suffer from a significant voltage drop.

### BRIEF DESCRIPTION OF THE DRAWINGS

FIG. 1 is an illustration of the configuration of pages of an MLC flash memory.

FIG. 2 is an illustration of the entire MLC flash memory and the configuration of its blocks.

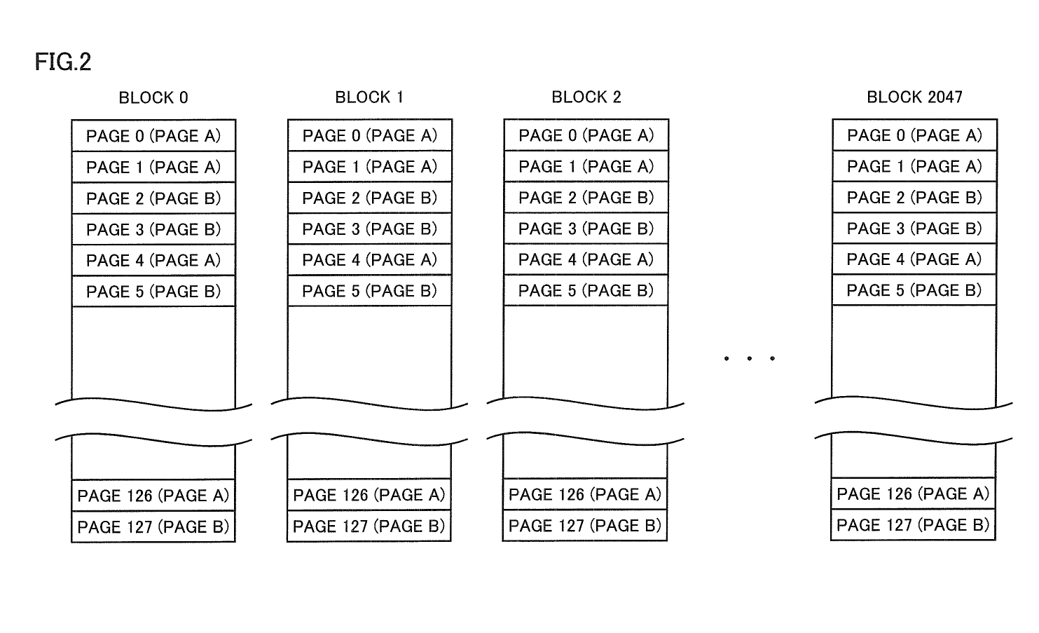

FIG. 3 is an illustration of transition states occurring during a program operation of data into each page of the MLC flash memory cell.

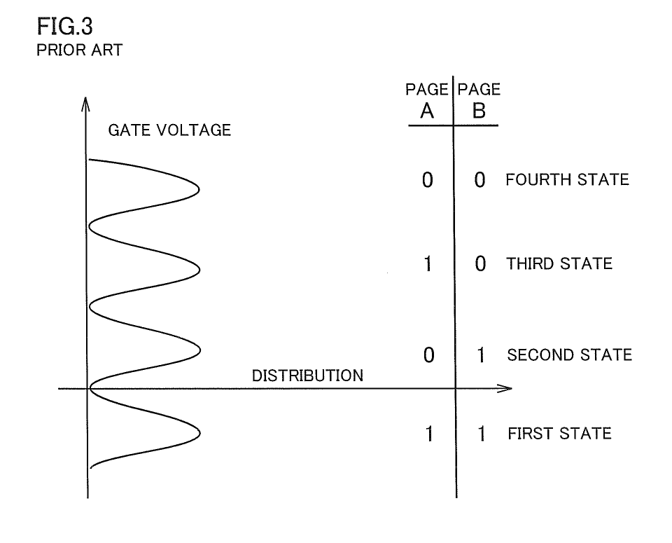

FIG. 4 is an illustration of when identical data is written to corresponding pages of two blocks of the MLC flash memory (Embodiment 1).

FIG. 5 is a block diagram showing a configuration of an MLC flash memory according to one embodiment of the present invention.

### DETAILED DESCRIPTION OF THE PREFERRED EMBODIMENT

### Embodiment 1

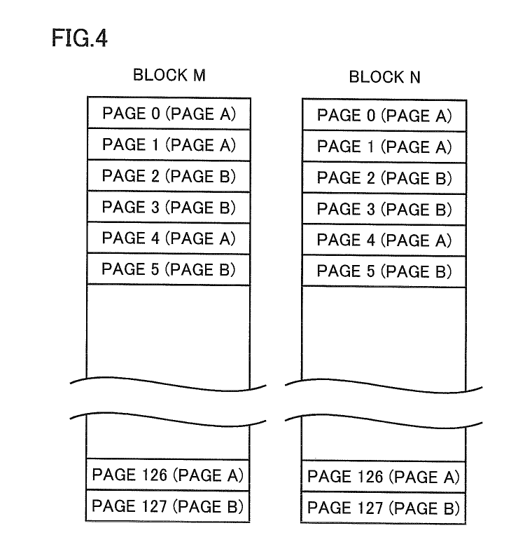

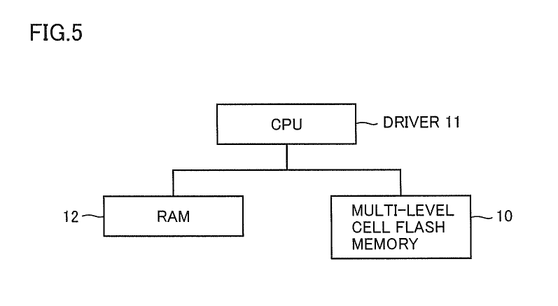

With reference to the drawings, embodiments of the present invention will be described below. FIG. 4 illustrates the configuration of blocks in a 4-level (2-bit/cell) flash memory, and FIG. 5 is a block diagram showing a configuration of an MLC flash memory according to one embodiment of the present invention. With reference to FIGS. 4 and 5, CPU 11 shown in FIG. 5 serves as the driver and operates as a program unit for writing data into memory cells in the flash memory. CPU 11 controls RAM 12 as well. Two blocks (block M and block N) are chosen to write data into page 0 of block M and then to write the same data into page 0 of block N. At this point, the data for page 0 is determined. In the same manner, identical data is written into the corresponding pages in the two blocks. Even if a power failure occurs in the middle of programming page A, like page 0 and page 1, the page can retain the written data. However, a power failure in the middle of programming page B, like page 2, may corrupt the data in page 0 which is page A in the same cell with page 2.

As mentioned above, the power failure in the middle of writing data into page 2 in block M may corrupt data in page 0 in block M; however; the content of page 0 will not be lost because page 0 in block N contains the same content as that in page 0 in block M. After recovery from the power failure, the data in page 0 in block N can be written into page 0 in a different block, the data in page 1 in block M is not corrupted and therefore can be written as it is into the other block, and the data, which was going to be written into page 2 before the power failure, can be written into page 2 in the other block. In the case where a power failure occurs in the middle of writing data into page 2 in block N, the data of page 0 in block N may be corrupted; however, because the same data stored in page 0 in block N exists in page 0 in block M, the possibly corrupted data can be restored by writing it into a different block again.

This method in which identical data is written in corresponding pages in two blocks chosen from a plurality of blocks always ensures data either in block M or block N. In this embodiment, writing the identical data into two pages in block M and block N up to page 127 realizes a proper program operation without regard to page A and page B.

### Embodiment 2

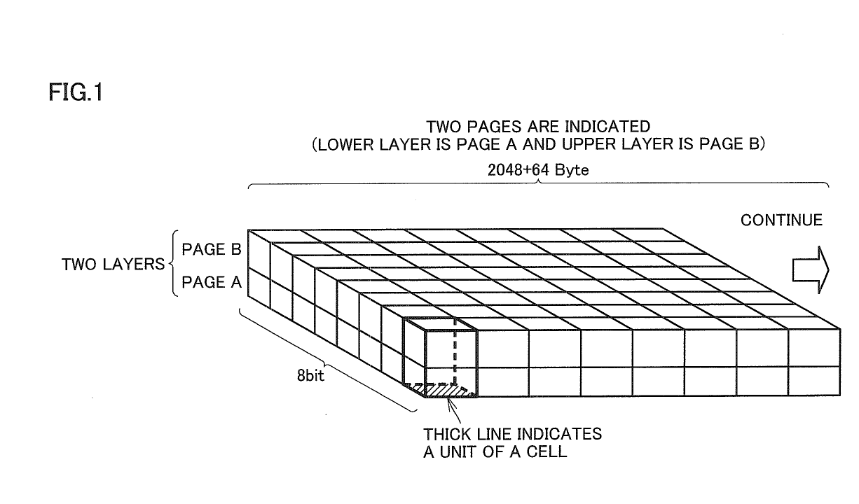

Next, an 8-level (3-bit/cell) flash memory will be described as another embodiment. The configuration of a page is assumed to have page C (not shown) on page A and page B shown in FIG. 1. A power failure in the middle of programming page A does not affect either page B or page C. However, a power failure during a program operation for page B does not affect page C, but may corrupt data in page A. In addition, if power is interrupted during a program operation for page C, data in both page A and page B may be corrupted. Although FIG. 4 shows only page A (64 pages) and page B (64 pages), it is assumed that there are 64 pages of page C (not shown). With this 8-level flash memory, a procedure of a program operation according to the present invention begins with page 0 (page A) in block M shown in FIG. 4 and then the same data is written into page 0 (page A) in block N. Next, data is written into page 1 (page A) in block M and then the same data is written into page 1 (page A) in block N. Furthermore, data is written into page 2 (page B) in block M and then the same data is written into page 2 (page B) in block N. As in the case of page A and page B, data is written into page C in block M and the same data is written into page C in block N in the same manner. According to the program operation, even if a power failure occurs, either block M or block N retains the written data just as the 4-level flash memory does.

A description will be made about how to select a valid block and to determine a valid page after a power failure. More specifically, the method to be described is for selecting a valid block and for determining a valid page at system startup after a power failure occurs in the middle of a program operation for writing identical data into the same numbered pages placed in two different blocks respectively and interrupts the program operation unexpectedly.

The two blocks are supposed to be block M and block N. Assuming that data is being written into a page numbered P (page P) in each block, and the program operation is executed to the Pth page in block M at first and then to the Pth page in block N.

A power failure occurring in the middle of programming the Pth page generates the following states shown in Table 1.

TABLE 1
The states upon power failures

| | | | valid block and page |
|---|---|---|---|
| | block M | block N | after power restoration |
| Page A | unprogrammed | Unprogrammed | p-0 |
| | partially | Unprogrammed | p-1 |
| | programmed | | |
| | fully programmed | Unprogrammed | p-2 |
| | fully programmed | partially | p-3 |
| | | programmed | |
| | fully programmed | fully programmed | p-4 |
| Page B | unprogrammed | Unprogrammed | p-0 |
| | partially | Unprogrammed | p-1 |
| | programmed | | |
| | fully programmed | Unprogrammed | p-2 |
| | fully programmed | partially | p-3 |
| | | programmed | |
| | fully programmed | fully programmed | p-4 |

Table 2 shows valid blocks and pages after power restoration as for each of the ten states in Table 1.

TABLE 2

| valid blocks and pages | valid | |
|---|---|---|
| after power restoration | blocks | valid pages |
| p-0 | block M | from the first page to the page |
| | | immediately before page P |
| p-1 | block N | from the first page to the page |
| | | immediately before page P |
| p-2 | block N | from the first page to the page |
| | | immediately before page P |
| p-3 | block M | from the first page to the page |
| | | immediately before page P |
| p-4 | block M | from the first page to page P |

The contents of the block that is not selected as a valid block are unprogrammed and the block will be used again.

A procedure by which the driver of the MLC flash memory determines a block and a page to be valid after power restoration will be described. More specifically, the driver determines the valid block M or N and valid pages in the block. In this description, the driver of the MLC flash memory operates as a valid-page determination unit.

Step 01: Block M and block N are fetched. Transition states in this procedure are represented by s-0, s-1, s-2, s-3, s-4 and s-5.

Step 02: The following steps are performed from the first page of blocks. The transition state is s-0. Page Q is the Qth page from the first page of the blocks. Every page, from the first page to the last page, advances through the following steps.

Step 03: The driver subjects the following steps to every page of the blocks to determine whether or not the following procedures are performed. The page to which the necessary procedures are performed goes to Step 15.

Step 04: Data in page Q in block M is read. This data is defined as data-m.

Step 05: Data in page Q in block N is read. This data is defined as data-n.

Step 06: The driver determines the state, among “unprogrammed”, “partially programmed” and “fully programmed”, that data-m is in.

Step 07: The driver determines the state, among “unprogrammed”, “partially programmed” and “fully programmed”, that data-n is in.

Step 08: The driver determines whether page Q is page A or page B. The determination result is stored.

Step 09: If both data-m and data-n are in the “unprogrammed” state, the driver goes to Step 15.

Step 10: If both data-m and data-n are in the “fully programmed” state and their data contents are identical as a result of comparison, the page is defined as being in transition state s-1. Page Q is advanced by one position and is subjected to the same procedure from Step 03.

Step 11: If data-m is in the “partially programmed” state and data-n is in the “fully programmed” state, the page is defined as being in transition state s-2. Page Q is advanced by one position and is subjected to the same procedure from Step 03.

Step 12: If data-m is in the “fully programmed” state and data-n is in the “partially programmed” state, the page is defined as being in state s-3. Page Q is advanced by one position and is subjected to the same procedure from Step 03.

Step 13: If data-m is in the “partially programmed” state and data-n is in the “unprogrammed” state, the page Q is defined as being in state s-4 and goes to Step 15.

Step 14: If data-m is in the “fully programmed” state and data-n is in the “unprogrammed” state, page Q is defined as being in state s-5 and goes to Step 15.

Step 15: According to the final transition state of page Q, the valid block and pages are determined from the Table 3 below.

TABLE 3

| transition | |
|---|---|
| state | block and page to be valid after power restoration |
| s-0 | There is no corrupted page in block M and block N because |
| | data has not been programmed yet. |
| s-1 | p-4 |
| s-2 | Pages pass through this transition state during the procedure, |
| | but go to s-1 at last. |
| s-3 | p-3 |
| s-4 | p-1 |
| s-5 | p-2 |

With an increasing demand for more storage capacity per memory which is equipped in a future embedded system that will grow in number, flash memories will be required to have more levels. In such a circumstance, the MLC flash memory with reinforced protection against power failures is indispensable and has a quite high advantage for industrial applicability.

What is claimed is:

1. An MLC flash memory representing more than two levels per cell wherein
said single cell includes a plurality of storage layers for holding the multiple levels;
a plurality of said cells make up a block;
said flash memory includes a plurality of said blocks;
said flash memory includes program unit to write data into said cells; and
said program unit selects two different blocks from said plurality of blocks and writes identical data into corresponding storage layers in the two selected blocks.
